(19) United States
(12) Patent Application Publication
(10) Pub. No.: US 2003/0119323 A1
(43) Pub. Date: Jun. 26, 2003

(54) Method for fabricating transistor in semiconductor device

(76) Inventor: Cheol Soo Park, Kyoungki-do (KR)

Correspondence Address: WILDMAN, HARROLD, ALLEN & DIXON, 225 WEST WACKER DRIVE, CHICAGO, IL, 60606, US

(21) Appl. No.: 10/325,318

(22) Filed: Dec. 19, 2002

(30) Foreign Application Priority Data
Dec. 24, 2001 (KR) 2001-84010

(51) Int. Cl. H01L 21/336

(52) U.S. Cl. 438/692; 438/691

(57) ABSTRACT

A method for fabricating a transistor in a semiconductor device can minimize short-channel effects (SCE), reverse short-channel effects (RSCE), gate induced drain leakage (GIDL), and off leakage of a transistor and can reduce production costs through fabricating the transistor through a simple process. The method comprises the steps of: forming a pad oxide layer on a silicon substrate wherein a field oxide layer has been formed, forming a nitride layer thereon, forming a gate conductor mask pattern on the nitride layer thereby patterning the nitride layer, forming a spacer at both sides of the nitride through blanket etching after forming a first insulating layer on the entire resultant structure, implanting impurities into the silicon substrate outside of the spacer thereby forming a source and drain region, forming an LDD implant in the silicon substrate outside of the nitride layer after removing the spacer through a wet etching process, performing a planarization through a chemical-mechanical polishing (CMP) process after forming a thick second insulating layer on the entire resultant structure, performing a channel threshold voltage implantation and a punch stop implantation in the silicon substrate after removing the nitride layer, performing a planarization through a CMP process after forming a gate insulating layer on an exposed part of the silicon substrate and forming a gate conductor thereon, forming a contact to connect the source and drain region with the gate conductor, stacking a conductor on the resultant structure, performing planarization through a CMP process, and performing a metal patterning to complete production of the transistor for a semiconductor device.

### BACKGROUND OF THE INVENTION

1. Field of the Invention

The present invention relates to a method for fabricating a transistor in a semiconductor device, and more particularly to a method for fabricating a transistor in a semiconductor device, which can minimize short-channel effects (SCE), reverse short-channel effects (RSCE), gate induced drain leakage (GIDL), and off leakage of a transistor which follows the high integration of the semiconductor device.

2. Description of the Prior Art

FIG. 1 is a cross-sectional view for illustrating a conventional method for fabricating a transistor in a semiconductor device.

As shown in FIG. 1, a buffer gate insulating layer 2a, a polysilicon layer 3a, and a hard mask layer 3b are sequentially stacked on a semiconductor substrate 1 wherein a desired thickness of a field oxide layer (not shown) has been formed.

Then, the hard mask layer 3b is patterned into a gate electrode shape, and the polysilicon layer 3a and the buffer gate insulating layer 2a are patterned into a hard mask layer 3b shape, resulting in the formation of a gate g.

Next, a spacer 5 is formed at both sides of the gate g through a method well-known in the art, and impurities are implanted into portions of the semiconductor substrate 1 located outside of the spacer 5 to form a source and drain region 6.

However, according to the conventional method for fabricating the transistor in the semiconductor device, it has been difficult to fabricate the short-channel transistor, and additional processes have been required to overcome short-channel effects (SCE) and reverse short-channel effects (RSCE) of the transistor.

Further, according to the conventional fabricating method for the transistor, the transistor has been made to have low threshold voltages by reducing the thickness of the gate and length of the gate in order to achieve low activating voltages and high integration. In this case, according to the conventional NMOS transistor, the characteristics of the semiconductor device have been lowered due to the increase of the leakage current originating from the reduction of the threshold voltages.

### SUMMARY OF THE INVENTION

Accordingly, the present invention has been made to solve the above-mentioned problems occurring in the prior art, and an object of the present invention is to provide a method for fabricating a transistor in a semiconductor device, which can minimize short-channel effects (SCE), reverse short-channel effects (RSCE), gate induced drain leakage (GIDL), and off leakage of a transistor in the semiconductor device.

Another object of the present invention is to provide a method for fabricating a transistor in a semiconductor device, which can reduce production costs by fabricating the transistor through a simple process.

In order to accomplish these objects, there is provided a method for fabricating a transistor in a semiconductor device comprising the steps of: forming a pad oxide layer on a silicon substrate wherein a field oxide layer has been formed, forming a nitride layer thereon, forming a gate conductor mask pattern on the nitride layer thereby patterning the nitride layer, forming a spacer at both sides of the nitride through blanket etching after forming a first insulating layer on the entire resultant structure, implanting impurities into the silicon substrate outside of the spacer thereby forming a source and drain region, forming an LDD implant in the silicon substrate outside of the nitride layer after removing the spacer through a wet etching process, performing planarization through a chemical-mechanical polishing (CMP) process after forming a thick second insulating layer on the entire resultant structure, performing a channel threshold voltage implant and a punch stop implant in the silicon substrate after removing the nitride layer, performing planarization through a CMP process after forming a gate insulating layer on an exposed part of the silicon substrate and forming a gate conductor thereon, forming a contact to connect the source and drain region with the gate conductor, stacking a conductor on the resultant structure, performing planarization through a CMP process, and performing a metal patterning, thereby accomplishing production of a transistor for a semiconductor device.

In this invention, the conductor is made of tungsten (W), and preferably is made of Ti/TiN/W.

Further, the conductor is formed through an epitaxial growing manner, and the nitride layer is removed in a hot H₃PO₄ environment.

### BRIEF DESCRIPTION OF THE DRAWINGS

The above and other objects, features and advantages of the present invention will be more apparent from the following detailed description taken in conjunction with the accompanying drawings, in which:

FIG. 1 is a cross-sectional view of a process for illustrating a method for fabricating a transistor in a semiconductor device according to the conventional art;

FIG. 2 is a planar view showing a layout used in the present invention and showing an isolation mask A and a gate conductor mask B;

FIGS. 3a to 3h are cross-sectional views for illustrating each step of the method for fabricating a transistor in a semiconductor device of the present invention.

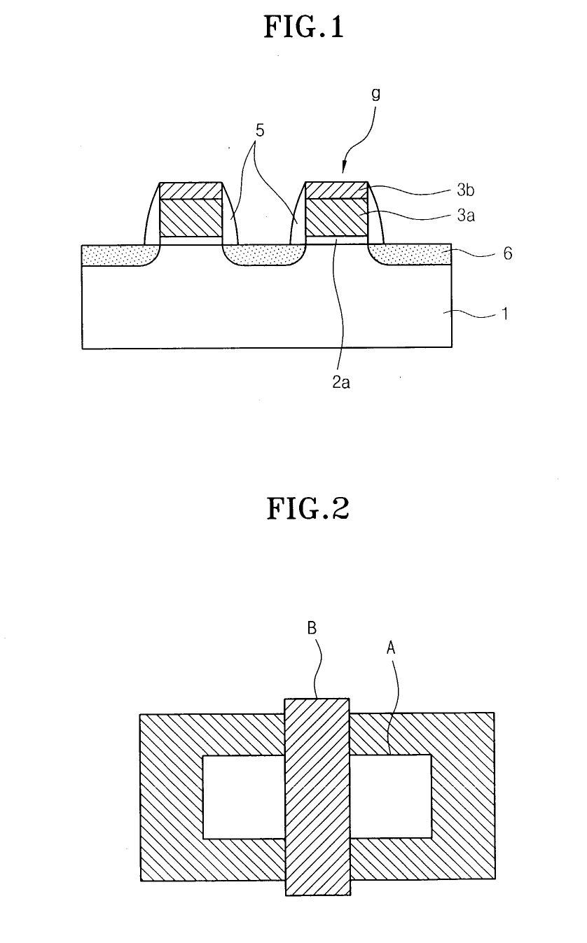

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

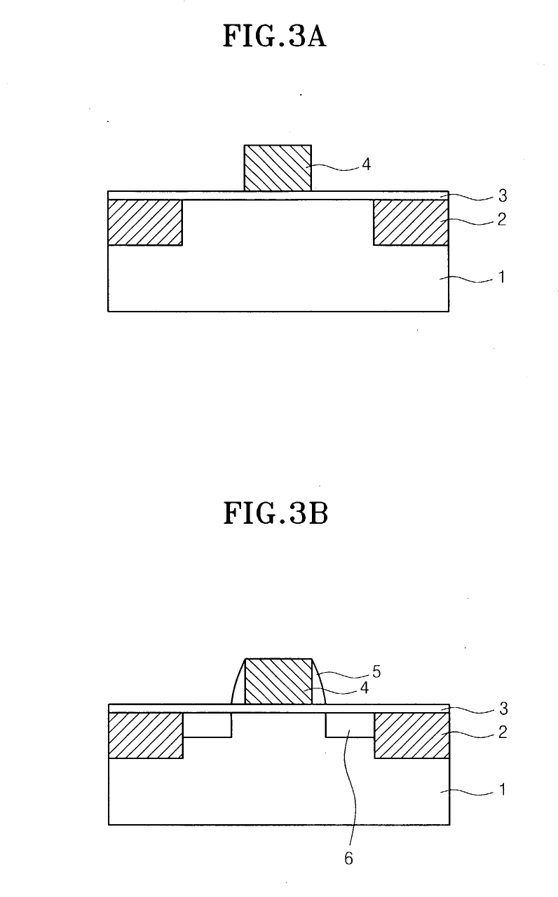

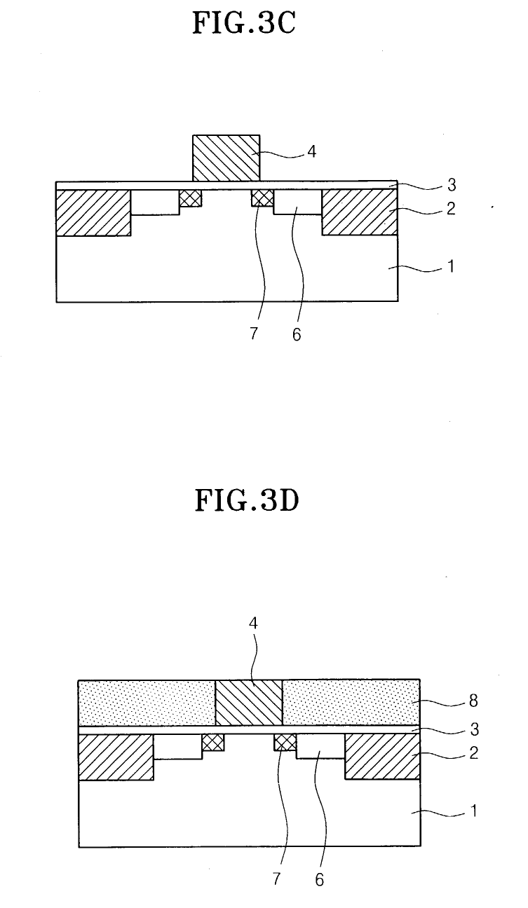

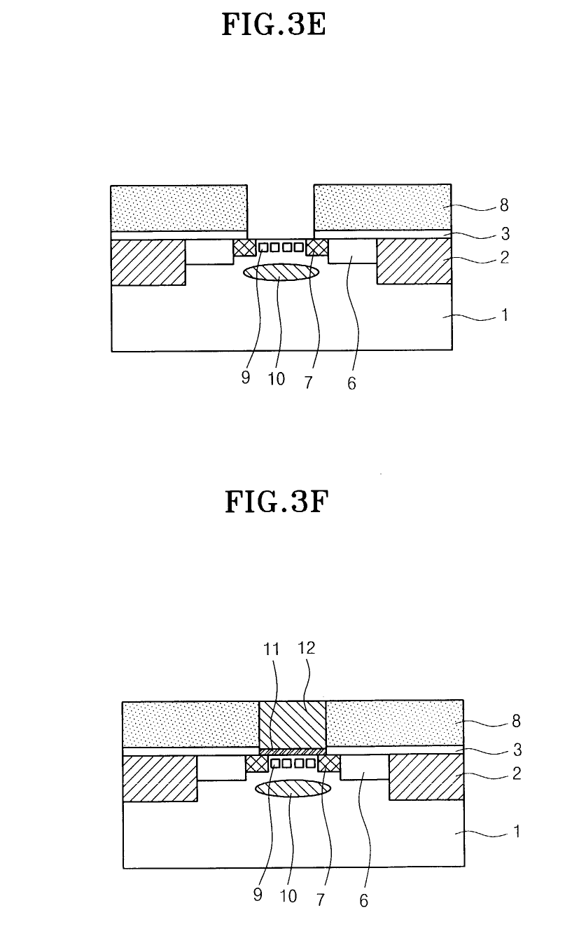

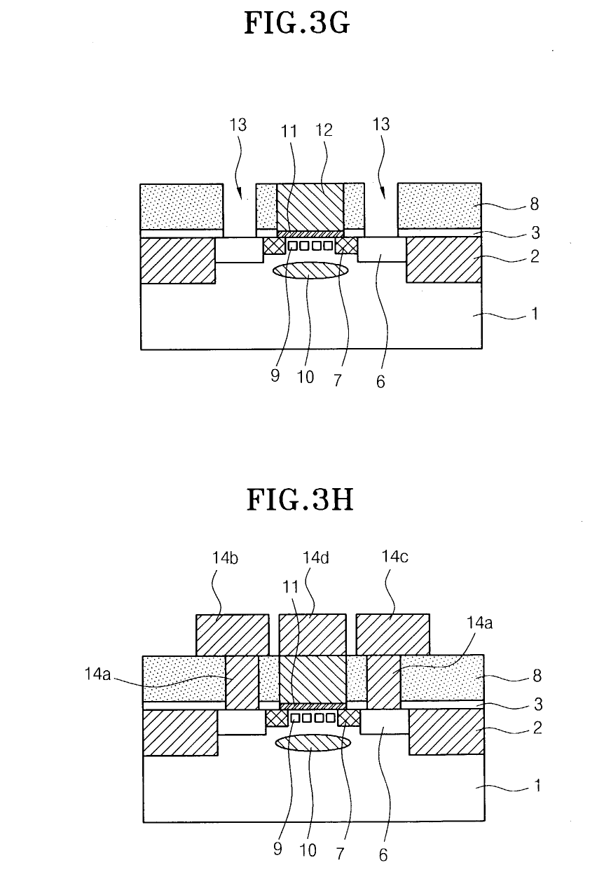

FIG. 2 is a planar view showing a layout used in the present invention and showing an isolation mask A and a gate conductor mask B, and FIGS. 3a to 3h are cross-sectional views for illustrating each step of the method for fabricating a transistor in a semiconductor device of the present invention.

Referring to FIG. 3a, a pad oxide layer 3 is formed on the silicon substrate 1 on which a field oxide layer 2 has already been formed beforehand, and a nitride layer 4 is next formed on the pad oxide layer 3. Then, a gate conductor mask pattern B is formed on the nitride layer 4, thereby patterning the nitride layer 4.

Referring to FIG. 3b, a first insulating layer (an oxide layer) is formed on the resultant structure of FIG. 3a, and a spacer 5 is formed at both sides of the nitride layer 4 by means of blanket etching. Then, impurities are implanted into the silicon substrate 1 outside of the spacer 5 to form a source and drain region 6.

Referring to FIG. 3c, the spacer 5 is removed through a wet etching process, and then an N-LDD (low doped drain) implant region or a P-LDD implant region 7 is formed through implanting an N-LDD implant or a p-LDD implant into the silicon substrate 1 outside of the nitride layer 4.

Referring to FIG. 3d, a second insulating layer 8 is stacked thickly on the resultant structure shown in FIG. 3c, and planarization is performed through a CMP (chemical-mechanical polishing) process.

Referring now to FIG. 3e, the nitride layer 4 is removed in a hot H₃PO₄ environment, and implantation is also performed to form a channel threshold voltage region 9 and a punch stop region 10 in the silicon substrate 1.

Referring to FIG. 3f, a gate insulating layer 11 is formed on an exposed part of the silicon substrate 1, and a gate conductor 12 is formed thereon, and planarization is performed through a CMP process of the resultant structure.

Referring to FIG. 3g, a contact 13 is formed to connect the source and drain region 6 and the implant region 7 with the gate conductor 12.

Then, referring to FIG. 3h, a conductor 14a, e.g., tungsten (W), preferably Ti/TiN/W, is layered on the resultant structure shown in FIG. 3g, planarization is performed through a CMP process, and metal patterning is performed, resulting in production of the transistors 14b, 14c, 14d.

As described above, according to the method for fabricating a transistor in a semiconductor device of the present invention, it is possible to minimize short-channel effects (SCE), reverse short-channel effects (RSCE), gate induced drain leakage (GIDL), and off leakage of a transistor. Also, production costs can be reduced because the transistor in the semiconductor device can be fabricated through a simple process.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A method for fabricating a transistor in a semiconductor device, comprising the steps of:
forming a pad oxide layer on a silicon substrate wherein a field oxide layer has already been formed beforehand;
forming a nitride layer thereon;
forming a gate conductor mask pattern on the nitride layer, thereby patterning the nitride layer;
forming a spacer at both sides of the nitride through blanket etching after forming a first insulating layer on the entire resultant structure;
implanting impurities into the silicon substrate outside of the spacer, thereby forming a source and drain region;
forming an LDD implant in the silicon substrate outside of the nitride layer after removing the spacer through a wet etching process;
performing a planarization through a chemical-mechanical polishing (CMP) process after forming a thick second insulating layer on the entire resultant structure;
performing a channel threshold voltage implantation and a punch stop implantation in the silicon substrate after removing the nitride layer;
performing planarization through a CMP process after forming a gate insulating layer on an exposed part of the silicon substrate and forming a gate conductor thereon;
forming a contact to connect the source and drain region with the gate conductor;
stacking a conductor on the resultant structure, and performing planarization through a CMP process, and then performing a metal patterning thereby accomplishing production of a transistor for a semiconductor device.

2. The method for fabricating a transistor according to claim 1, wherein the conductor is made of tungsten (W).

3. The method for fabricating a transistor according to claim 1, wherein the conductor is made of Ti/TiN/W.

4. The method for fabricating a transistor according to claim 1, wherein the conductor is formed through an epitaxial growing manner.

5. The method for fabricating a transistor according to claim 1, wherein the nitride layer is removed in a hot H₃PO₄ environment.
